(19) United States
(12) Patent Application Publication
(10) Pub. No.: US 2010/0015782 A1
(43) Pub. Date: Jan. 21, 2010

(54) Wafer Dicing Methods

(76) Inventors: Chen-Hua Yu, Hsin-Chu (TW); Wen-Chih Chiou, Miaoli (TW); Ding-Yuan Chen, Taichung (TW)

Correspondence Address: SLATER & MATSIL, L.L.P., 17950 PRESTON ROAD, SUITE 1000, DALLAS, TX, 75252, US

(21) Appl. No.: 12/175,818

(22) Filed: Jul. 18, 2008

(51) Int. Cl. H01L 21/00

(52) U.S. Cl. 438/463; 257/E21.001

(57) ABSTRACT

Semiconductor wafer dicing methods are disclosed. These methods include forming etch patterns between adjacent semiconductor dice to be separated. Various etch processes can be used to form the etch patterns. The etch patterns generally reach a pre-determined depth into the wafer substrate significantly beyond the wafer top layer where pre-fabricated semiconductor dice are embedded. Semiconductor dice may be separated from a post-etch, large-sized, frangible wafer through wafer grinding, mechanical cleaving, and laser dicing approaches. Preferred embodiments result in reduced wafer-dicing related device damage and improved product yield.

### TECHNICAL FIELD

The present invention relates generally to wafer dicing methods, and more particularly to methods of separating semiconductor wafers into chips.

### BACKGROUND

Upon the completion of semiconductor manufacturing processes, a large number of duplicate semiconductor devices, such as light emitting diode (LED) devices are typically formed on a semiconductor wafer. These devices are separated by scribe lines on the processed wafer. Various techniques are employed to divide the processed wafers along the scribe lines into individual dice with each die representing a particular semiconductor device chip. Typical wafer dicing techniques adopted today include mechanical cleaving, laser dicing, and sawing with diamond blade.

The method of mechanical cleaving involves pre-cracking a scribe line with a diamond tip and manually breaking the wafer along the scribe line, similar to the way a plate glass is cut for household purposes. The technique of laser dicing employs a high-energy laser beam striking on the scribe line, blasting the micro-structure of the wafer crystalline material and forming the dicing cuts. The method of sawing separates dice on a wafer using diamond saw blades. However, when used on wafers made of frangible semiconductor materials to divide semiconductor device dice of miniature die size, these known wafer dicing methods may not provide satisfactory results. The method of mechanical cleaving and sawing leaves micro-cracks along the edges of the dicing cuts. These cracks can easily propagate on a wafer through unexpected crack paths, which may lead to significant device damage and substantial device yield loss. The yield loss may become increasingly severe on wafers having devices with miniature die sizes, as can be appreciated. The effects of vibrating, shearing, and shocking accompanying a sawing operation may aggravate the cracking and create more device damages and yield losses. Also, the physical dimension of a diamond saw blade limits the further scaling of the scribe lines on a semiconductor wafer, which inhibits the pervasive trend of scaling down the scribe line dimensions on a wafer and rending the maximum possible wafer area to functional semiconductor devices in advanced processing technology. In addition, when laser dicing is used, the high-energy laser strikes on the wafer surface may create a large amount of wafer material particles in the ambient. These particles may re-deposit back on the wafer and cause severe particle contaminations. Besides, the high-energy laser beam may also cause micro-cracks as a result of the localized high-heating of the wafer crystalline material.

Furthermore, the trend of increasing wafer diameter in semiconductor manufacturing continues as, as part of the effort to increase the throughput of a semiconductor fabrication facility and offset the high cost imposed by the processing equipment in advanced processing technology. As another well known trend, high luminance and high power light emitting semiconductor devices, and high sensitivity light emitting device with reduced device size are gaining broader adaptation in various application fields. Such light emitting device wafers are typically brittle and more sensitive to mechanical damage than conventional silicon-based wafers. These trends generally promote developing new wafer dicing methods.

### SUMMARY OF THE INVENTION

These and other problems are generally solved or circumvented, and technical advantages are generally achieved, by preferred embodiments of the present invention which provide improved wafer dicing methods of separating semiconductor dice on a semiconductor wafer. These methods include forming etch patterns between adjacent semiconductor dice to be separated. Various etch processes can be used to form the etch patterns. The etch patterns generally reach a pre-determined depth into the wafer substrate significantly beyond the wafer top layer where pre-fabricated semiconductor dice are embedded. Semiconductor dice may be separated from a post-etch, large-sized, frangible wafer through wafer grinding, mechanical cleaving, and laser dicing approaches. Preferred embodiments result in reduced wafer-dicing related device damage and improved product yield

In accordance with a preferred embodiment of the present invention, a method for separating a plurality of semiconductor device dice formed in a top surface layer of a wafer substrate comprises forming a photolithography pattern on the top surface layer, exposing an area between adjacent dice to be separated, etching the exposed area to a depth in the wafer substrate substantially below the substrate top surface layer, and thinning the back surface until the etched pattern in the wafer substrate is exposed.

In accordance with another preferred embodiment of the present invention, a method for separating a plurality of semiconductor device dice formed in a top surface layer of a wafer comprises forming a photolithography pattern on the top surface layer, exposing an area between adjacent dice to be separated, etching the exposed area to a depth in the wafer substantially below the top surface layer, and shining a laser beam into the etched pattern to cut through the wafer and separate the dice from each other.

In accordance with yet another preferred embodiment of the present invention, a method for separating a plurality of LED device dice formed in a top surface layer of a wafer substrate comprises forming a photolithography pattern on the top surface layer, exposing an area between adjacent LED dice to be separated, etching the exposed area to a depth in the wafer substrate substantially below the substrate top surface layer, and thinning the back surface until the etched pattern in the wafer substrate is exposed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-5 are cross-sectional views of processing steps according to one embodiment of the present invention;

FIG. 6 is a cross-sectional view of an illustrative embodiment of the present invention; and

FIG. 7 is a cross-sectional view of an illustrative embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely improved wafer dicing methods. The preferred embodiments may be used to separate a large diameter, frangible semiconductor wafer into dice having miniature die size. The preferred embodiments significantly ease the handing of the wafers to be separated, and may significantly alleviate or even eliminate the detrimental effects, such as micro-cracking and particle re-deposition associated with the conventional wafer dicing methods, therefore reducing the dicing-related device damage and improving product yield. Also, the preferred embodiments do not require adding complex processing equipments and processing steps.

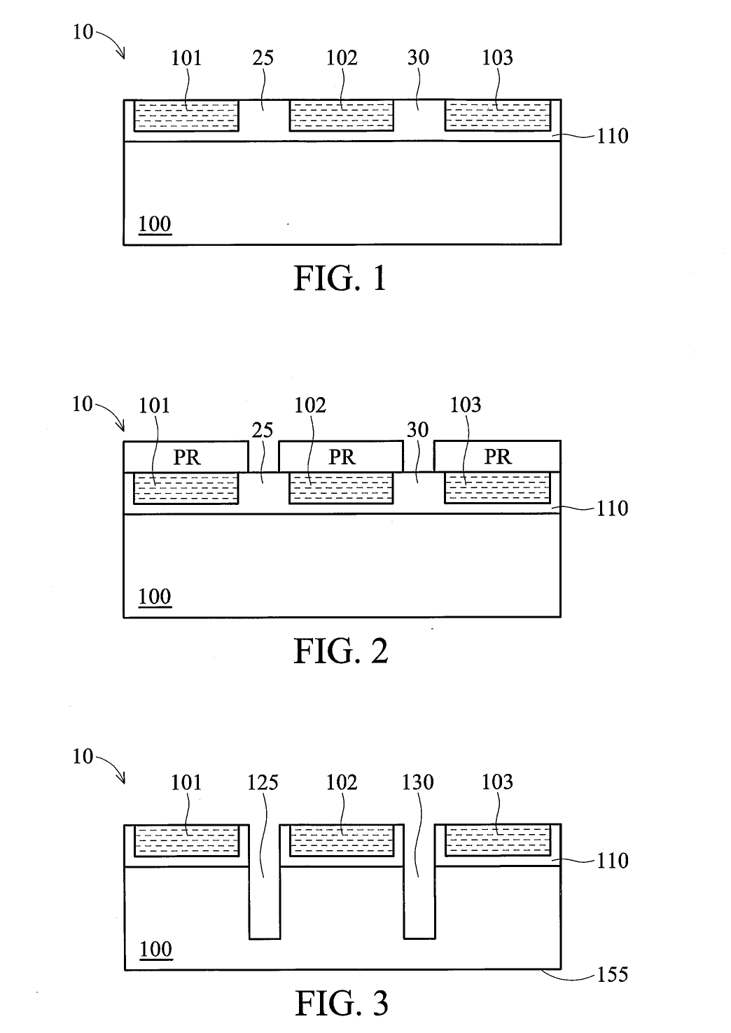

With reference now to FIG. 1, there is shown a portion of a cross-sectional diagram of semiconductor wafer 10. Wafer 10 comprises substrate 100 and a top layer 110 formed atop substrate 100. Semiconductor device dice 101, 102, and 103 have been processed and embedded into top layer 110, each comprising one or more active and passive electronic devices, such as MOS transistors, radio frequency devices, optoelectronic devices, and the like. Semiconductor device dice 101, 102, and 103 may be in the form of a light emitting diode (LED), a semiconductor laser diode, and the like. To simplify description, top layer 110 is shown as a single layer, but in reality, top layer 110 may comprise active layers over substrate 100 where active and/or passive devices are formed, interconnect metal layers coupling the devices forming functional circuits, and an overlying protective passivation layer, as well known to those skilled in the art.

Various wafer configurations are employed in preferred embodiments. In one embodiment, substrate 100 may be made of gallium arsenide (GaAs), gallium arsenide-phosphide (GaAsP), indium phosphide (InP), gallium phosphide (GaP), gallium aluminum arsenic (GaAlAs), indium gallium phosphide (InGaP), and the like, and devices 101, 102, and 103 comprise light-emitting diodes (LEDs). In another embodiment, substrate 100 is sapphire substrate, and the top layer includes Gallium nitride (GaN)/Indium gallium nitride (InGaN) LEDs.

LED devices 101, 102, and 103 represent a plurality of dice occupying essentially the entire top layer of processed semiconductor wafer 10. Regions 25 and 30 represent the spaces between adjacent LED dice, the spaces being the grid-like scribe line regions surrounding the plurality of dice in one preferred embodiment. Preferred embodiments operate at those regions to separate wafer 10 into individual dice in a manner that significantly alleviates or even eliminates wafer-dicing related device damage, and improves device yield loss and device reliability.

In FIG. 2, a photolithography process is performed on wafer 10, exposing a portion of the regions between adjacent LED dice, such as a portion of regions 25 and 30 between LED dice 101, 102, and 103, as shown, while masking the LED die areas with a patterned photoresistive coating. A known photolithography process in an existing semiconductor manufacturing process is employed in one preferred embodiment.

Continuing in FIG. 3, an etch process is applied on wafer 10 to remove top layer 110 and a portion of substrate 100 in the exposed areas of wafer 10, forming etch patterns between adjacent LED dice to be separated, such as trenches 125 and 130 shown in FIG. 3. In one preferred embodiment, a time-controlling anisotropic plasma etch process is conducted on wafer substrate 100 to create deep trenches having a depth of about 2-75 microns. In another preferred embodiment, an anisotropic plasma etch process creates an etch pattern in wafer 100, which reaches a depth greater than half of the wafer thickness of from about 600 microns to about 1000 microns. As well known in the art, an anisotropic plasma etch process is capable of forming a substantially vertical etch profile with a large aspect ratio (depth vs. width), thus anisotropic plasma etch is particularly useful when semiconductor dice are densely formed on a semiconductor wafer and the spaces between adjacent dice become very small.

In another preferred embodiment, an isotropic etch process, e.g., wet etch, is performed to create isotropic etch patterns between adjacent semiconductor dice to be separated. As an example, semiconductor devices 101, 102, and 103 are LEDs formed in a top layer 110 of about 20 microns on gallium arsenide (GaAs) wafer substrate 100 of about 600 microns, a wet etch solution comprising HF or KOH is used to form grooves reaching a depth from about 100 microns to about 150 microns in substrate 100. In additional and/or alternative embodiments, other suitable dry or wet etch processes may also be used taking account of factors such as technical requirement, process availability, process cost, throughput, etc.

It should be noted that, regardless of the etch process used, the etch patterns of 125 and 130 generally reach a pre-determined depth into wafer substrate 100 significantly beyond wafer top layer 110 where semiconductor dice are embedded. For example, in the case of a sapphire substrate processed to form LEDs 101, 102, and 103 in the top GaN/InGaN layer, the etch profile should reach a depth in the sapphire substrate far beyond the PN junction regions in the GaN/InGaN layer. In preferred embodiments, the etch patterns reach a depth in substrate 100 so that the distance between the bottom of the etched patterns 125, 130 and the backside 155 of wafer 10 is in the range of from about 200 microns to about 350 microns.

After the formation of etch profiles between adjacent semiconductor dice to be separated, the photoresist covering the dice are removed.

FIG. 4 illustrates a subsequent process step following the etch process described with respect to FIG. 3 in one preferred embodiment. Wafer 10 is mounted on a carrier disc, for example, sapphire disc 200 as shown. In doing so, wafer 10 is flipped over and the top layer 101 is bound to sapphire disc 200 with ultraviolet (UV) backgrinding tape 180. The wafer backside is subsequently ground and polished until the substrate portion between the etch patterns and wafer backside 155 are substantially removed. As a consequence, etch patterns 125 and 130 are exposed or revealed and semiconductor dice 101 through 103 are separated.

It is noted that wafer grinding is an existing processing step commonly practiced after semiconductor wafers are fabricated in a semiconductor fabricating facility (FAB), and prior to the wafers being diced and packaged. One of the advantages of grinding the wafers is to improve the heat dissipation characteristic of the chips. Therefore, wafer grinding in preferred embodiments may be conducted with an existing wafer grinding facility and does not require added processing equipment and processing steps.

UV backgrinding tape 180 binds wafer 10 to carrier 200. Compared with wax and non-UV backgrinding tapes typically used in an existing wafer grinding process, UV tape 180 provides stronger adhesion to secure a wafer during an aggressive grinding process accompanying vibrating, shearing, and shocking. This characteristic is specifically desirable in securing miniature semiconductor dice during the dicing to prevent semiconductor die movement and fly-off. The improved adhesion of UV tape 180 also enables strong bonds for non-standard substrates, such as FR-4 and ball grid array (BGA) substrates. A suitable UV tape used in preferred embodiments includes Semiconductor Tapes and Materials, Inc.'s TSM GT-UV-224 UV backgrinding tape. Acid resistant UV tapes are also available on the market, which is chemically inert to etchants used in an etch process.

FIG. 5 illustrates separated dice 101, 102, and 103 bound to carrier 200. Up to this point of the dicing process, semiconductor dice on wafer 10 are all separated, but are stilled attached to carrier 200 via UV tape 180.

Next, semiconductor dice on wafer 10, such as 101, 102, and 103, are removed from carrier 200. When UV backgrinding tape 180 is used, the removal may be accomplished through a UV curing process, which exposes wafer 10 and carrier 200 to UV light. The adhesiveness of UV backgrinding tape 180 reduces significantly after UV curing, thus facilitating detaching separated IC dice from carrier 200. In the current embodiment, a UV exposure dosage of about 150 mJ/cm² (365 nm) is used to substantially neutralize the UV tape adhesion. This is especially beneficial when dice are small and thin in size and comprise frangible materials. As an example, the current embodiment is performed to divide LED dies each having a dimension of about 2 mm by 2 mm separated by scribe lines having a dimension of about 150 microns (0.15 mm). Additional advantageous features include that the current wafer dicing approach leaves wafer surface free of impurities, contaminations, and other residues. Additionally, the UV-cured, non-sticky dice may greatly ease their handling in the subsequent packaging and testing processes.

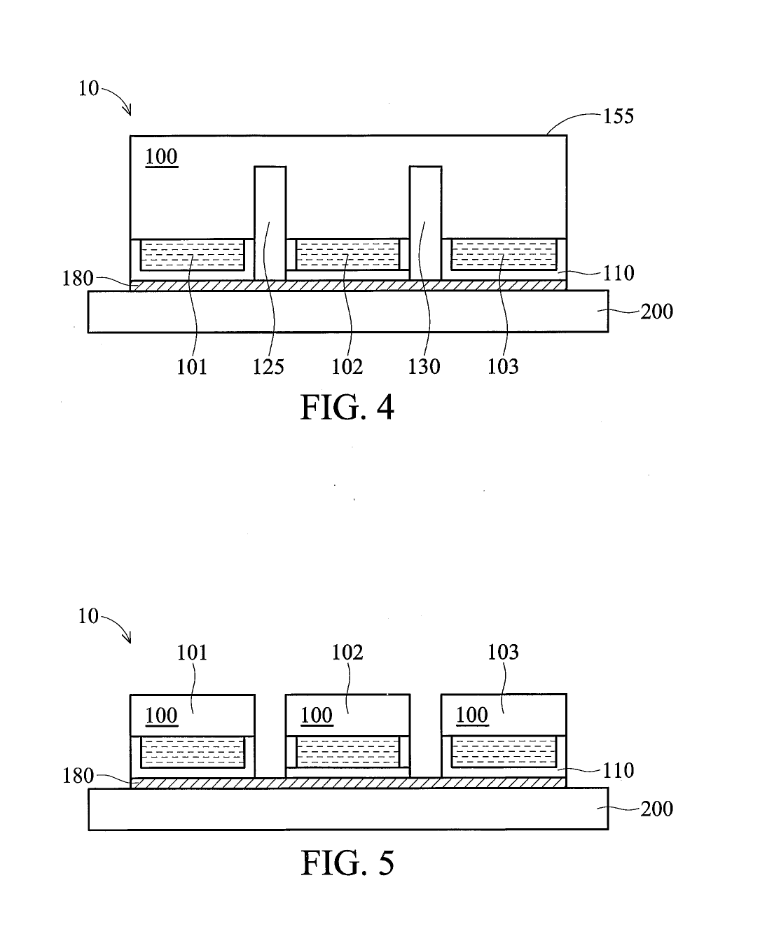

As shown in FIG. 6 of another preferred embodiment, after the etch patterns are formed between adjacent dice to be separated, such as trenches 125 and 130 in FIG. 3, a conventional mechanical cleaving approach may be subsequently applied in the IC dice. A substantially smaller mechanical force is needed to bend wafer 10 and separate dice 101, 102, and 103 because the dice to be separated are attached to each other by a thin layer of substrate material of about 200-350 microns. Additionally, micro-cracks stemming from the mechanical cleaving occur largely at the bottom of the etch patterns, far beyond the dice, as shown. This may significantly reduce dicing-related device damage and yield loss. In the current embodiment, an existing two-profile or a three-profile mechanical cleaving wheel may be engaged on post-etched wafer 10 to separate dies formed thereon.

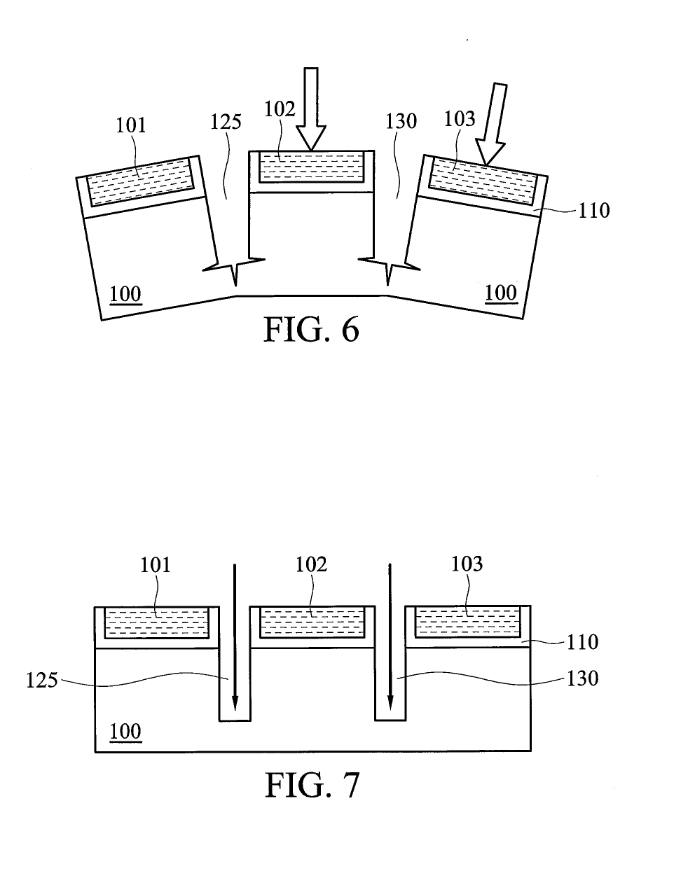

Similarly, shown in FIG. 7 with respect to an additional preferred embodiment, after the etch patterns are formed between adjacent dice to be separated, such as trenches 125 and 130 in FIG. 3, a laser dicing approach may be subsequently applied to wafer 10. Unlike the prior art laser dicing method, high energy laser beams (solid arrows in FIG. 7) in the current embodiment are delivered to the bottom of the etch patterns, away from the surface of the dice. The current laser dicing approach separates semiconductor dice much faster due to significantly reduced cutting depth. Other advantageous features include: wafer material particles created by the laser strikes are confined in the etch patterns, alleviating or preventing particle re-deposition to the wafer surface. Similarly, micro-cracks created by laser-heating are close to the etch pattern bottom, far from the die areas.

Although the preferred embodiments and their advantages have been described in detail with respect to LED devices, it should be understood by those skilled in the art that the wafer dicing methods disclosed in preferred embodiments are also applicable to other semiconductor fields. As an example, substrate 100 may be also a bulk crystalline semiconductor material, such as silicon (Si), germanium (Ge), silicon germanium (SiGe), and top layer 101 includes an epitaxial layer with doped N-well and/or doped P-well regions where active and passive semiconductor devices are fabricated to form integrated circuits (ICs) 101, 102, and 103, such as a digital IC, an analog IC, a mixed signal IC, an radio frequency (RF) IC, a microwave microstrip device, an IC having a system-on-a-chip configuration, a micro-electromechanical system (MEMS), and the like. As another example, substrate 100 comprises an insulating layer, such as a sapphire or a buried silicon oxide (BOX) layer, and top layer 110 is a semiconductor layer formed on the insulating layer, having a silicon-on-insulator (SOI) wafer configuration. In an alternative and/or additional embodiment, substrate 100 is an FR-4 printed circuit board (PCB) or a ceramic substrate and semiconductor dice 101, 102, and 103 comprises surface or embedded microstrip devices.

It should also be understood the preferred embodiments described above are merely exemplary to illustrate the concept that device damage and yield loss in related to the conventional wafer dicing approaches can be minimized or avoided. The preferred embodiments are especially beneficial to separate miniature semiconductor dice on a large and frangible semiconductor wafer. Various changes, substitutions and alterations can be made herein without departing from the spirit and scope of the invention as defined by the appended claims. As another example, it will be readily understood by those skilled in the art that materials, process steps, process parameters in forming the preferred embodiments may be varied while remaining within the scope of the present invention.

Moreover, the scope of the present application is not intended to be limited to the particular embodiments of the process, machine, manufacture, composition of matter, means, methods and steps as described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for separating a plurality of semiconductor device dice formed in a top surface layer of a wafer substrate comprising:
forming a photolithography pattern on the top surface layer, exposing an area between adjacent dice to be separated;
etching the exposed area to a depth in the wafer substrate substantially below the substrate top surface layer; and
thinning the back surface until the etched pattern in the wafer substrate is exposed.

2. The method according to claim 1 wherein the wafer substrate comprises a material selected from the group consisting of: gallium arsenide (GaAs), gallium arsenide-phosphide (GaAsP), indium phosphide (InP), gallium phosphide (GaP), gallium aluminum arsenic (GaAlAs), indium gallium phosphide (InGaP), gallium nitride (GaN), Indium gallium nitride (InGaN), GaN/InGaN on sapphire, silicon (Si), germanium (Ge), silicon germanium (SiGe), and a printed circuit board (PCB), and combinations thereof.

3. The method according to claim 1 wherein the semiconductor devices comprise one selected from the group consisting of: a light emitting diode device (LED), an active semiconductor, a passive device, an integrated circuit (IC), a radio frequency IC, a microwave microstrip device, an optoelectronic device, a micro-electromechanical system (MEMS) device, and combinations thereof.

4. The method according to claim 1 further comprising mounting the top surface layer of the wafer to a wafer grinding carrier via ultraviolet (UV) back grinding tape, thereby exposing a back surface of the wafer.

5. The method according to claim 1 wherein the etching is performed by a plasma etch process.

6. The method according to claim 1 wherein the etching is performed by a wet etch process with an etch solution selected from the group consisting of: HF and KOH.

7. The method according to claim 1 wherein the etching extends in the wafer substrate to a depth in the range of from about 2 microns to about 75 microns.

8. The method according to claim 1 wherein the etching extends to a depth in the wafer such that the bottom of the etched pattern and the back surface of the wafer are about 200 microns to about 350 microns from each other.

9. The method according to claim 4 further comprising: curing the wafer and the grinding carrier with a UV exposure so that the adhesiveness of the UV backgrinding tape is substantially neutralized.

10. The method according to claim 9 wherein the UV exposure has an UV dosage of about 150 mJ/cm².

11. The method according to claim 1 wherein the semiconductor device dice each has a dimension of about 1 mm by 1 mm and the wafer comprises a 2″ sapphire substrate.

12. A method for separating a plurality of semiconductor device dice formed in a top surface layer of a wafer comprising:
forming a photolithography pattern on the top surface layer, exposing an area between adjacent dice to be separated;
etching the exposed area to a depth in the wafer substantially below the top surface layer; and
shining a laser beam into the etched pattern to cut through the wafer and separate the dice from each other.

13. The method according to claim 12 wherein the wafer substrate comprises a material selected from the group consisting of: gallium arsenide (GaAs), gallium arsenide-phosphide (GaAsP), indium phosphide (InP), gallium phosphide (GaP), gallium aluminum arsenic (GaAlAs), indium gallium phosphide (InGaP), gallium nitride (GaN), Indium gallium nitride (InGaN), GaN/InGaN on sapphire, silicon (Si), germanium (Ge), silicon germanium (SiGe), and a printed circuit board (PCB), and combinations thereof.

14. The method according to claim 12 wherein the semiconductor devices comprise one selected from the group consisting of: a light emitting diode device (LED), an active semiconductor, a passive device, an integrated circuit (IC), a radio frequency IC, a microwave microstrip device, an optoelectronic device, a micro-electromechanical system (MEMS) device, and combinations thereof.

15. The method according to claim 12 wherein the etching comprises a plasma etch process, and wherein the etched pattern reaches a depth in the wafer substrate substantially greater than the top surface layer inlaid with LED devices.

16. A method for separating a plurality of LED device dice formed in a top surface layer of a wafer substrate comprising:
forming a photolithography pattern on the top surface layer, exposing an area between adjacent LED dice to be separated;
etching the exposed area to a depth in the wafer substrate substantially below the substrate top surface layer; and
thinning the back surface until the etched pattern in the wafer substrate is exposed.

17. The method according to claim 16 wherein the wafer substrate comprises a material selected from the group consisting of: gallium arsenide (GaAs), gallium arsenide-phosphide (GaAsP), indium phosphide (InP), gallium phosphide (GaP), gallium aluminum arsenic (GaAlAs), indium gallium phosphide (InGaP), gallium nitride (GaN), Indium gallium nitride (InGaN), GaN/InGaN on sapphire, and combinations thereof.

18. The method according to claim 16 further comprising:
mounting the top surface layer of the wafer to a wafer grinding carrier via ultraviolet (UV) back grinding tape, thereby exposing a back surface of the wafer; and
curing the wafer and the grinding carrier with a UV exposure so that the adhesiveness of the UV backgrinding tape is substantially neutralized.

19. The method according to claim 16 wherein the etching is performed by a plasma etch process and extends in the wafer substrate to a depth in the range of from about 2 microns to about 75 microns.

20. The method according to claim 16 wherein the LED device dice each has a dimension of about 1 mm by 1 mm and the wafer comprises a 2″ sapphire substrate.
